(19) United States
(12) Patent Application Publication
(10) Pub. No.: US 2011/0127993 A1
(43) Pub. Date: Jun. 2, 2011

(54) Position Monitoring Device, System and Method

(75) Inventor: George E. Pearce, Lafayette, LA (US)

(73) Assignee: BAKER HUGHES INCORPORATED, Houston, TX (US)

(21) Appl. No.: 12/629,551

(22) Filed: Dec. 2, 2009

(51) Int. Cl. H01L 43/06

(52) U.S. Cl. 324/207.2

(57) ABSTRACT

A position monitoring system includes, two Hall-effect sensors in operable communication with one another such that they produce a single output, the two Hall-effect sensors having opposing polarities functionally directed toward one another.

### BACKGROUND

Hall-effect sensors are commonly used in position monitoring systems. The Hall-effect sensor, however, limits a travel dimension that can be monitored. Additionally, such systems generate a single output value for multiple positions thereby rendering the results ambiguous and problematic. Devices and methods to extend dimensions of position monitoring without the foregoing drawbacks are desirable in the art.

### BRIEF DESCRIPTION

Disclosed herein is a position monitoring system. The system includes, two Hall-effect sensors in operable communication with one another such that they produce a single output, the two Hall-effect sensors having opposing polarities functionally directed toward one another.

Further disclosed herein is a method of monitoring a position. The method includes, positioning two Hall-effect sensors with opposing polarities facing one another, combining outputs of the two Hall-effect sensors into a single output, and moving a magnet along a path such that the magnet is in operable communication with at least one of the two Hall-effect sensors at all locations

Further disclosed herein is a position monitoring device. The device includes, a first Hall-effect sensor, and a second Hall-effect sensor positioned with an opposing polarity to the first Hall-effect sensor, the first Hall-effect sensor and the second Hall-effect sensor are in operable communication such that they produce a combined output in response to a magnet moved relative to the first Hall-effect sensor and the second Hall-effect sensor.

### BRIEF DESCRIPTION OF THE DRAWINGS

The following descriptions should not be considered limiting in any way. With reference to the accompanying drawings, like elements are numbered alike:

FIG. 1 depicts a schematic view of a position monitoring system disclosed herein with an output versus magnet position curve superimposed therebelow;

FIG. 2 depicts a magnified view of an area of a first Hall-effect sensor of FIG. 1;

FIG. 3 depicts an end view of the device illustrated in FIG. 2;

FIG. 4 depicts a position monitoring system disclosed herein in a downhole safety valve application; and

FIG. 5 depicts a schematic view of an alternate position monitoring system disclosed herein.

### DETAILED DESCRIPTION

A detailed description of one or more embodiments of the disclosed apparatus and method are presented herein by way of exemplification and not limitation with reference to the Figures.

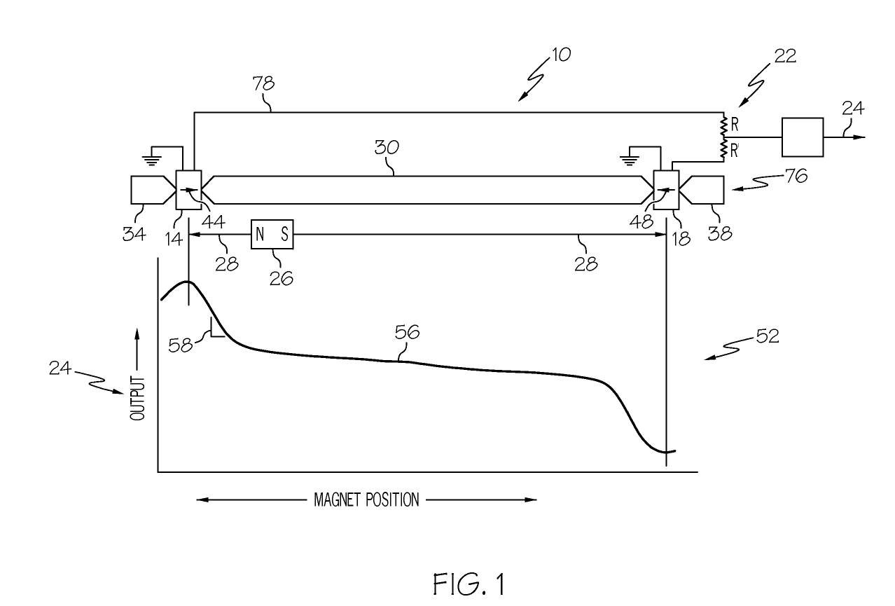

Referring to FIG. 1, an embodiment of a position monitoring system disclosed herein is illustrated generally at 10. The position monitoring system 10 includes, a first Hall-effect sensor 14 and a second Hall-effect sensor 18 in a circuit 22 configured to produce a single output signal 24 representative of the composite or combined output of the two Hall-effect sensors 14, 18, and a magnet 26 in continuous operable communication with at least one of the two Hall-effect sensors 14, 18 throughout a range of travel of the magnet 26 defined by arrows 28. A mid-pole piece 30, made of magnetically permeable material, is positioned between the two Hall-effect sensors 14, 18. A first magnetically permeable end-pole piece 34 is positioned adjacent the first Hall-effect sensor 14 on a side opposite a side that the mid-pole piece 30 is located, while a second magnetically permeable end-pole piece 38 is positioned adjacent the second Hall-effect sensor 18 on a side opposite a side that the mid-pole piece 30 is located, as such the end-pole pieces 34, 38 are outboard of the Hall-effect sensors 14, 18. A first polarity of the first Hall-effect sensor 14 as indicated by arrow 44 is opposite to a second polarity of the second Hall-effect sensor 18 as indicated by arrow 48.

In the illustrated embodiment the Hall-effect sensors 14, 18 are of the bipolar type. A bipolar Hall-effect sensor has the desirable characteristic that a singe such sensor outputs a “neutral voltage” that is about half of the voltage supplied to the sensor when no magnetic field is sensed and then outputs a changed voltage in response to sensing of a magnetic field, i.e. presence of the magnet 26. For the first Hall-effect sensor 14, for example, with the first polarity the voltage output increases from the neutral voltage upon sensing a magnetic field, and for the second Hall-effect sensor 18, with the second (inversed) polarity, the voltage output decreases from the neutral voltage upon sensing a magnetic field. As such, by combining the outputs of the two Hall-effect sensors 14, 18, with opposing polarities, into the single output signal 24 the output is made to be continuous and monotonic in response to movement of the magnet 26 in either direction.

As shown in graph 52, depicting the single output signal 24 versus position of the magnet 26, the foregoing structure produces a monotonic output 24 for all positions of the magnet 26 along its full range of travel. In other words, a sign of a slope 58 of the curve 56 remains constant (the slope 58 being always negative in this embodiment) over a full range of movement of the magnet 26. As such, every position of the magnet 26 has a unique value of the output 24 associated therewith providing an unambiguous indication of position of the magnet 26. The system 10 therefore allows an operator to know a magnet position without having to continuously monitor the output 24 (as is necessary with a system providing ambiguous outputs, since, in an ambiguous system, it would be necessary to know which of the plurality of possible positions is being indicated by the ambiguous output).

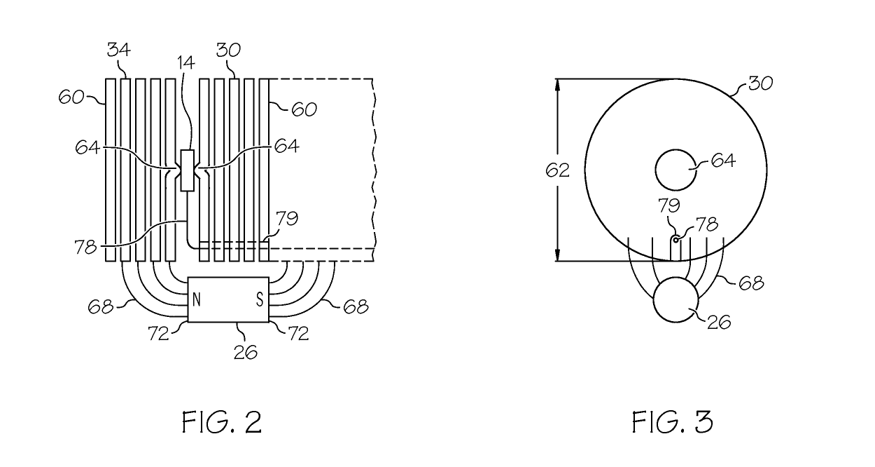

Referring to FIGS. 2 and 3, the first end-pole piece 34 and the mid-pole piece 30 are shown in this embodiment as a stack of laminations 60. A dimple 64 formed near the center of laminations abutting the hall sensor concentrate the magnetic flux 68 from the magnet 26 to the first Hall-effect sensor 14, which in this embodiment is much smaller in size than an outer dimension 62 of the laminations 60. A total effective air gap (TEAG), defined by totaling the gaps between each of the magnet ends 72 and the laminations 60, and between the dimples 64 of the first end-pole piece 34 and the first Hall-effect sensor 14, and the mid-pole piece 30 and the first Hall-effect sensor 14, are kept to a minimum to maintain a high signal-to-noise ratio. Additionally, the circular shape of the laminations 60 and the centralized position of the dimples 64 and the Hall-effect sensors 14, 18 relative thereto, allow a sensor subassembly 76 (see FIG. 1) (defined as a combination of the Hall-effect sensors 14, 18, circuit 22, and pole pieces 30, 34, 38), to be insensitive to rotational orientation relative to the magnet 26. This can simplify assembly of the sensor subassembly 76 to a housing for example by not requiring orientational locking details or assembly processes to be utilized. Routing at least one electrical lead 78 through a slot 79, or bore hole, in the laminations 60 from one of the Hall-effect sensors 14, 18 toward the other Hall-effect sensor 14, 18 may be needed, however, such routing should be achievable without detrimentally affecting the rotational insensitivity discussed.

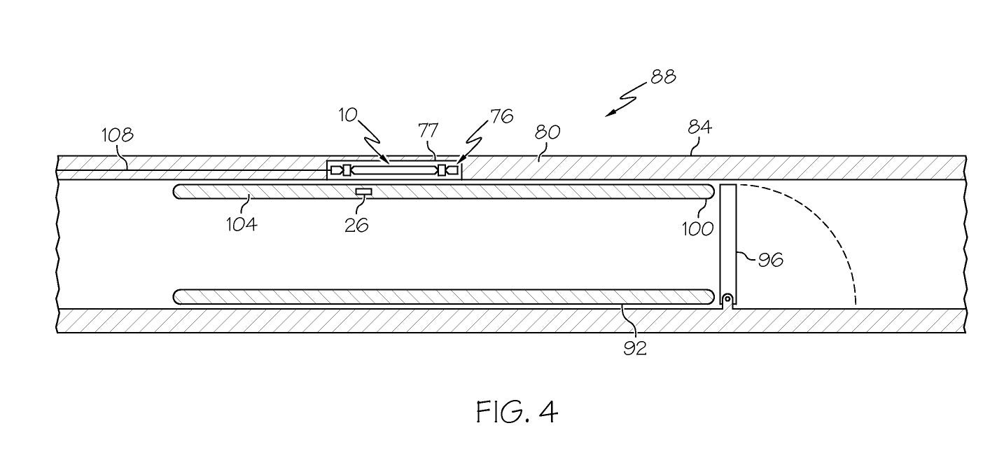

Referring to FIG. 4, the sensor subassembly 76 is installed in a window 77 formed in a wall 80 of a tubular 84 in a downhole application illustrated herein as a safety valve 88. The safety valve 88 includes a flow tube 92 longitudinally movable within the tubular 84 from the closed position (as illustrated) to an open position (not shown) in response to movement of the flow tube 92 (rightward in the figure). Movement of the flow tube 92 rightward holds a flapper 96, sealably engagable with an end 100 of the flow tube 92, in an open position. Installing the magnet 26 on a wall 104 of the flow tube 92 (the flow tube 92 being rotationally aligned with the sensor subassembly 76), and optionally extending the magnet 26 into the window 77 allows the output 24 to positively indicate a longitudinal position of the magnet 26 in relation to the sensor subassembly 76. The structural relationship of the magnet 26 to the flow tube 92, the flow tube 92 to the flapper 96, and the flapper 96 to the tubular 84 allows an operator to know a relative opening of the flapper 96 in relation to the end 100, by knowing the position of the magnet 26 relative to the subassembly 76. The single signal nature of the output 24 of the circuit 22 allows the output 24 to be communicated to a remote location, such as surface, via a single communication channel 108 indicated here as a wired pipe although any communication technology could be employed. The monotonic nature of the output 24 of the position monitoring system 10 provides a well operator with the ability to leave the system in a powered down mode until a status of the open condition of the safety valve 88 is desired, at which time the operator simply powers up the system 10, reads the output 24, and determines the position of the flapper 96 that correlates thereto. Although, in this embodiment, the position monitoring system 10 has been applied to the safety valve 88 alternate tools such as, actuators, seals and slips, for example, are contemplated.

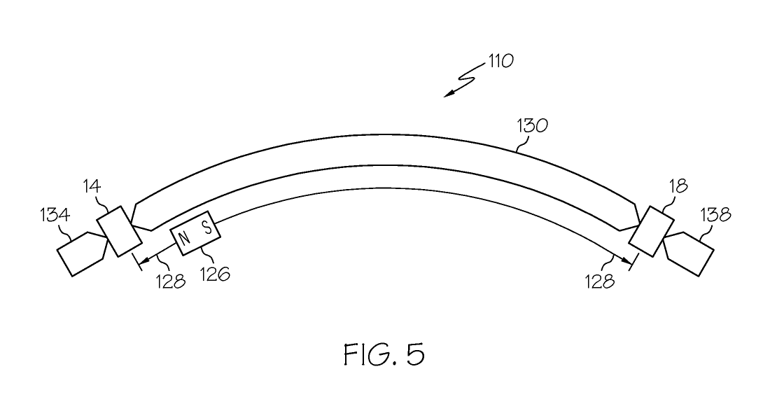

Referring to FIG. 5, an alternate embodiment of a position monitoring system is illustrated generally at 110. The sensor 110 differs from the sensor 10 mainly in that mid-pole 130, end-poles 134, 138 and a path of travel of the magnet 26, indicated by arrows 128, are in the form of a circular arc instead of being aligned a linear path as they are in the sensor 10. As such, the sensor 110 can be used to sense rotational position instead of linear position. Additional embodiments having alternate geometries of position sensing, although not illustrated, are contemplated, such as, a helical position sensor, for example.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A position monitoring system comprising two Hall-effect sensors in operable communication with one another such that they produce a single output, the two Hall-effect sensors having opposing polarities functionally directed toward one another.

2. The position monitoring system of claim 1, further comprising a magnet movable relative to the two Hall-effect sensors being in continuous operable communication with at least one of the two Hall-effect sensors, the position monitoring system being configured to produce a monotonic output for magnet positions substantially spanning a dimension between the two Hall-effect sensors.

3. The position monitoring system of claim 2, further comprising a mid-pole piece positioned between the two Hall-effect sensors.

4. The position monitoring system of claim 3, further comprising at least one end-pole piece positioned on an opposing side of at least one of the two Hall-effect sensors from the mid-pole piece.

5. The position monitoring system of claim 3, wherein the magnet is movable in a path substantially parallel with the mid-pole piece.

6. The position monitoring system of claim 3, wherein the mid-pole piece is magnetically permeable.

7. The position monitoring system of claim 3, wherein the two Hall-effect sensors and the mid-pole piece are positioned substantially along a straight line.

8. The position monitoring system of claim 3, wherein the two Hall-effect sensors and the mid-pole piece are positioned substantially along a circular arc.

9. The position monitoring system of claim 2, wherein a sign of a slope of the monotonic output versus magnet displacement curve is constant.

10. The position monitoring system of claim 1, wherein the two Hall-effect sensors are bipolar sensors.

11. A method of monitoring a position comprising:
positioning two Hall-effect sensors with opposing polarities facing one another;
combining outputs of the two Hall-effect sensors into a single output; and
moving a magnet along a path such that the magnet is in operable communication with the two Hall-effect sensors.

12. The method of monitoring a position of claim 11, further comprising positioning correlating the single output unambiguously to a position of the magnet relative to the two Hall-effect sensors.

13. The method of monitoring a position of claim 11, further comprising positioning a mid-pole piece between the two Hall-effect sensors.

14. The method of monitoring a position of claim 11, further comprising reporting the single output over a single communication channel.

15. The method of monitoring a position of claim 11, wherein the moving of the magnet is such that the magnet is in operable communication with at least one of the two Hall-effect sensors at all locations.

16. A position monitoring device, comprising:
a first Hall-effect sensor; and
a second Hall-effect sensor positioned with an opposing polarity to the first Hall-effect sensor, the first Hall-effect sensor and the second Hall-effect sensor being in operable communication such that they produce a combined output in response to a magnet moved relative to the first Hall-effect sensor and the second Hall-effect sensor.

17. The position monitoring device of claim 16 wherein the combined output is monotonic.

18. The position monitoring device of claim 16 further comprising a mid-pole piece positioned between the first Hall-effect sensor and the second Hall-effect sensor.

19. The position monitoring device of claim 18 wherein the mid-pole piece is configured to concentrate magnetic flux relative to at least one of the first Hall-effect sensor and the second Hall-effect sensor.

20. The position monitoring device of claim 18 further comprising a first end-pole piece positioned on a side of the first Hall-effect sensor opposite to a side where the mid-pole piece is positioned.

21. The position monitoring device of claim 18 further comprising a second end-pole piece positioned on a side of the second Hall-effect sensor opposite to a side where the mid-pole piece is positioned.

22. The position monitoring device of claim 16 wherein the combined output is insensitive to a rotational orientation of a sensed magnet relative to a longitudinal extent of the first Hall-effect sensor and the second Hall-effect sensor.

23. The position monitoring device of claim 16 wherein the first Hall-effect sensor and the second Hall-effect sensor are configured to sense position of a magnet moved along a circular arc.

24. The position monitoring device of claim 16 wherein the combined output correlates to a magnet moved fully between the first Hall-effect sensor and the second Hall-effect sensor.

25. The position monitoring device of claim 16 wherein the First Hall-effect sensor and the second Hall-effect sensor are disposed at a downhole tool and configured to sense a magnet moved relative to the First Hall-effect sensor and the second Hall-effect sensor.

26. The position monitoring device of claim 16 further comprising a circuit configured to report the combined output over a single communication channel.
